(19) United States
(12) Patent Application Publication
(10) Pub. No.: US 2006/0130889 A1
(43) Pub. Date: Jun. 22, 2006

(54) Solar panel with optical films

(75) Inventors: Zili Li, Barrington, IL (US); Dennis G. Anson, Coral Springs, FL (US)

Correspondence Address: FLEIT, KAIN, GIBBONS, GUTMAN, BONGINI;& BIANCO P.L., 551 N.W. 77TH STREET, SUITE 111, BOCA RATON, FL, 33487, US

(73) Assignee: MOTOROLA, INC., SCHAUMBURG, IL (US)

(21) Appl. No.: 11/020,534

(22) Filed: Dec. 22, 2004

(51) Int. Cl. H01L 25/00

(52) U.S. Cl. 136/244; 136/246

(57) ABSTRACT

A solar panel mounting arrangement, and electronic device, and a wireless device, includes a solar panel (204); and a wavelength selectively reflective optical film (202) being disposed in front of the solar panel for the optical film to substantially reflect a pre-selected band (304) of solar irradiation frequencies (302) in the visible light range and incident on a front surface of the optical film (202) while allowing solar irradiation frequencies (302) outside of the pre-selected band (304) to substantially pass through the optical film (202) and irradiate the solar panel (204). The optical film (202) can include at least one of an iconic pattern, a company logo, and a photo, that is visible from the front of the optical film (202). The optical film (202) can include holographic film. The optical film can include a multi-layer film.

### FIELD OF THE INVENTION

The present invention generally relates to the field of solar cells and electronic devices that utilize solar cells, and more particularly relates to solar panels and optical films utilized by electronic devices such as wireless communication devices and cellular phones.

### BACKGROUND OF THE INVENTION

Electronic devices, such as wireless communication devices including cell phones, portable two-way radios, wireless communicators, and the like, are being used by a large range of users for a wide variety of applications. As demand for newer features and functions increases, power consumption demands continue to increase from an energy source, typically a rechargeable battery, found in many portable wireless communication devices such as cell phones. The life of a battery is very important to users of portable electronic devices, including users of wireless communication devices. A short battery life can be detrimental to the commercial viability of a product such as a wireless communication device. Unfortunately, advancements in energy source technology have not been able to keep pace with additional new features that continue to additionally drain the energy source on wireless communication devices. This is an ongoing problem.

Solar cells, or sometimes referred to as solar panels, represent a supplemental or alternative source of energy for some electronic devices. Some devices, such as portable calculators, have both sufficiently large available surface area and sufficiently low power needs that some of these electronic devices have been powered entirely by one or more solar cells. Unfortunately, many electronic devices, including for example cellular telephones and other wireless communications devices have had both a higher power demand and an often-limited available surface area for locating a solar cell on the outer surface of the device. As a result, solar cells have not been viewed as a satisfactory supplemental or alternative power source for such devices.

While there has been a constant need in improving power performance of a portable electronic device, such as a wireless communication device, and while solar power solutions have been promising, one of the issues with solar panel technology is its very unappealing appearance, being mostly very dark with shining electrodes on its surface. This generates a great mismatch in the visual appearance between the solar panel and the exterior of the hosting electronic device. This problem is particularly severe with consumer products to which users associate a high premium value with respect to product aesthetics and particularly to a product's external cosmetic appearance.

Therefore a need exists to overcome the problems with the prior art as discussed above.

### SUMMARY OF THE INVENTION

According embodiments of the present invention, a solar panel mounting arrangement, and electronic device, and a wireless device, includes a solar panel; and a wavelength selectively reflective optical film being disposed in front of the solar panel for the optical film to substantially reflect a pre-selected band of solar irradiation frequencies incident on a front surface of the optical film while allowing solar irradiation frequencies outside of the selected band to substantially pass through the optical film and irradiate the solar panel. The substantially reflected pre-selected band of solar irradiation frequencies can be in the visible light range.

The optical film can include at least one of an iconic pattern, a company logo, and a photo, that is visible from the front of the optical film. The optical film can be of the holographic film type.

The solar panel can be located outside or inside a housing of the device while allowing solar irradiation outside of the housing to substantially irradiate the solar panel. In the case where the solar panel is inside the housing, at least a portion of the housing is substantially optically transparent to solar irradiation.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is plan view of an exemplary electronic device with a solar panel on the battery door exterior surface of the electronic device.

FIG. 2 is a plan view of a solar panel with an optical film label suitable for use in an electronic device, such as the exemplary electronic device of FIG. 1, according to an embodiment of the present invention.

FIG. 3 is a chart showing irradiance vs. wavelength for solar spectrum, an exemplary reflective curve of an optical film, and an exemplary normalized solar cell response.

FIG. 4 illustrates a block diagram of an exemplary electronic device according to an embodiment of the present invention.

FIG. 5 is a front plan view of an exemplary electronic device according to an embodiment of the present invention.

FIG. 6 is side cross-sectional view of an electronic device housing, with a solar panel and an optical film disposed on the exterior surface of the housing, according to a first exemplary embodiment of the present invention.

FIG. 7 is side cross-sectional view of an electronic device housing, with a solar panel and an optical film disposed on the interior surface of the housing, according to a second exemplary embodiment of the present invention.

FIG. 8 is a front perspective view of a housing of an exemplary wireless device with the front side of the housing removed, illustrating an array of solar panels being disposed on various surfaces of the housing, according to an exemplary embodiment of the present invention.

### DETAILED DESCRIPTION

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically.

The present invention, according to an embodiment, overcomes problems with the prior art by providing a new and novel solar panel arrangement including a wavelength selectively reflective optical film, a wavelength selectively reflective holographic film, or similar reflective structure, disposed in front of a solar panel to significantly enhance the aesthetic appearance of the solar panel while minimally degrading, if at all, the efficiency of conversion of solar energy by the solar panel. The new and novel solar panel arrangement can be disposed on various surfaces of a housing of an electronic device, including external surfaces and/or internal surfaces of the housing.

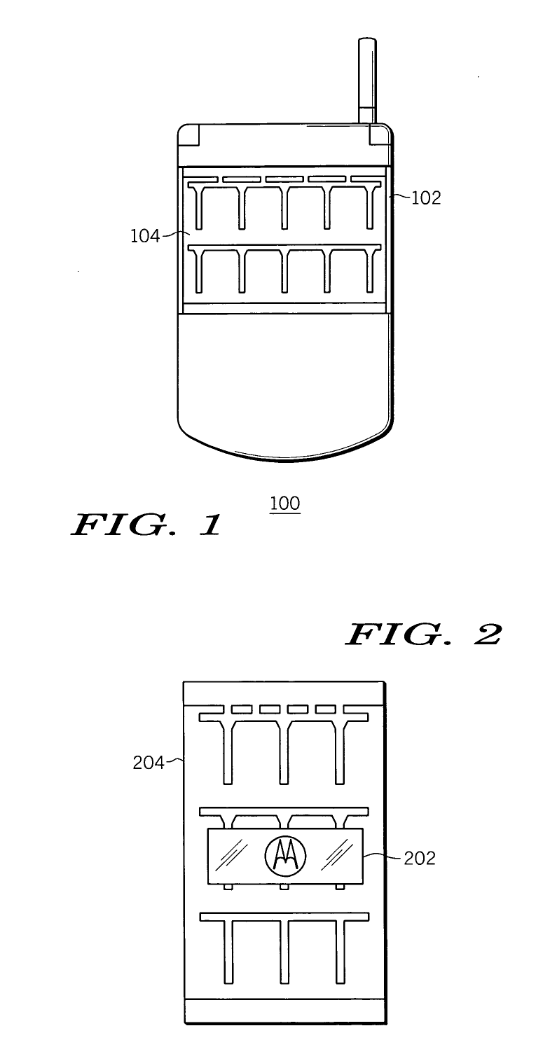

FIG. 1 illustrates a solar panel 104 being disposed on an exterior surface of an exemplary electronic device, such as the wireless device or cell phone 100 being shown. In this example, the solar panel 104 is disposed on a battery door surface 102 of the cell phone 100. The solar panel in this example is a single crystal silicon based solar panel. As can be seen, the solar panel 104 is aesthetically unattractive due to its visible large black panel with bright metallic electrodes.

As shown in FIG. 2, a solar panel 204, representative of the solar panel 104 shown in FIG. 1, can be disposed behind a wavelength selectively reflective optical film, or holographic film, or the like, being generally referred to herein as optical film 202. Note also that the optical film 202, according to alternative embodiments, may comprise a multi-layer film. In this example, the film 202 reflects a narrow pre-selected band of frequencies of light that are visible by a user of the cell phone 100 and at the same time the film 202 allows most wavelengths outside of the pre-selected band of frequencies (other than the reflected wavelengths) of solar irradiation to pass through the film 202 and reach the solar panel 204. In this way, the solar panel 204 benefits from a significantly enhanced aesthetic appearance to a user of the device 100 while impacting the performance of the solar panel 204 to a small degree, if at all. To maximize the power collection with such a combination, the selective reflection band wavelength of the film 202 should be adjusted away from the peak of the absorption band of the solar panel 204. At the same time, the wavelength of the selective reflective band of the optical film should be tuned to maximize its visual appearance to human eyes. Furthermore, an iconic pattern such as a company logo (see the exemplary film 202 shown in FIG. 2) or a photo can be embedded into the optical film to create a more desired visual effect or for advertising value.

Commercial grade holographic films that are useful for alternative embodiments of the present invention are manufactured by, and commercially available from, a number of manufacturers, such as Dupont and Dai Nippon. Holographic film products are sold under different brand names for a variety of applications. Further, the tuning of wavelengths for an optical film to enhance visual appearance can be done by recording and playing back methods and mechanisms that are well known to those of ordinary skill in the relevant art. Furthermore, suitable multi-layer films made of plastic or polymeric materials are manufactured by, and commercially available from, the 3M Company. Other types of narrow band optical films suitable for various alternative applications of the present invention are manufactured by, and are commercially available from, various manufacturers, as should be obvious to those of ordinary skill in the art in view of the present discussion. For example, a cholesteric liquid crystal film is available from Dai Nippon or from Merck.

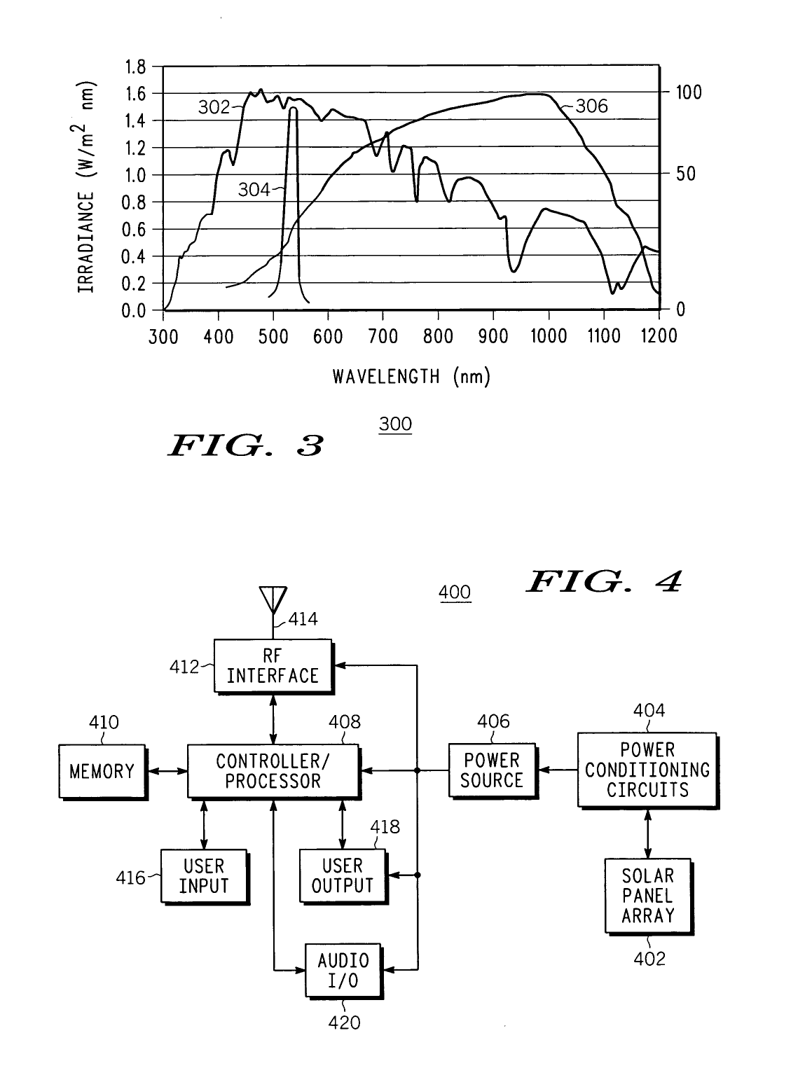

FIG. 3 is a chart that illustrates the relationships between the irradiance of the solar spectrum 302, the representative reflection band of optical film 304, and the normalized solar cell response 306. Note that the optical film reflection 304 is a narrow band that in one embodiment is pre-selected by design to be away from the peak region of the solar cell response 306. In this way, while the user visually sees the reflected light providing an aesthetically pleasing appearance to the user, the solar cell response 306 is minimally, if at all, degraded by the exemplary optical film 202 (see FIG. 2). By adding this type of optical film 202 and solar panel 204 arrangement, an electronic device 100 can achieve drastically improved overall visual appearance while maintaining acceptable power collection characteristics for the solar panel 204.

The wavelength of the reflective band 304 of the optical film 202 is tuned, in one embodiment, to maximize its visual appearance to human eyes. An iconic pattern such as a company logo or photo can be embedded into the optical film 202 to create a more desired visual effect or for advertising value. One such optical film 202 comprises a holographic film that can be made to reflect different colors of ambient lights while transmitting the complementary wavelength portion of the ambient light. Note also that the optical film 202, according to alternative embodiments, may comprise a multi-layer film without deviating from the teachings of the present invention.

A combination of a visible wavelength selectively reflective optical film 202 and an underneath solar panel 204 can be disposed at any surface of a housing of an electronic device, including any combination of external and internal surfaces of the housing, as will be discussed in more detail below. The optical film, in one embodiment, can be attached to the solar panel via an optically clear adhesive, or by other means that allows significant transmission of solar irradiance to reach the solar panel. To maximize the power collection with such a combination, the selective reflection band wavelength 304 of the film 202 should be adjusted away from the peak region of the absorption band 306 of the solar panel 204. At the same time, the wavelength of the reflective band 304 of the optical film 202 should be tuned to maximize its visual appearance to human eyes. Furthermore, an iconic pattern such as a company logo or photo can be embedded into the optical film to create a customized visual effect. This visual design and appearance of the optical film 202 can be chose for advertising purposes. For example, a marketing message, a customized image, or other combination of visible elements tailored for particular customers or particular market segments, can be combined in the visible appearance of the optical film 202. This new and novel arrangement of optical film disposed in front of a solar panel utilizes the externally visible surface area both for aesthetically pleasing appearance and for advertising. This visible surface area would have been otherwise wasted by a conventional solar panel located on an exterior surface of an electronic device.

A test was performed using an exemplary iDEN cellular phone manufactured by Motorola, Inc. A commercially available solar flex, identified as an Iowa Thinfilm MPT3.6-37 1.5″×2.5″ solar flex, was mounted onto an iDEN cell phone battery door. A tester wore this cell phone on the tester's belt as it would be normally used in a typical outdoor environment. The solar flex produced an average of 66 mW (18 mA/3.6 volt) over a 7 hour period or 454 mWHr. This level of performance would provide a significant amount of power to improve the battery performance of a cell phone. The same solar flex, was then combined with a holographic film arranged in front of the solar flex. The hologram used in this test was green color. When the solar flex was fully covered by the holographic film, the power measurement yielded an over 80% power collection (or less than 20% power reduction) as compared with a solar flex without the added holographic film. The visual appearance of the cell phone was also drastically enhanced, especially with a hologram with iconic pattern being visible to a user instead of the black with silver metallic electrodes of the solar flex.

Moreover, the iconic optical film approach discussed above could be designed to cover only a small portion of the overall solar flex, while maintaining the enhanced visual appearance of the cell phone. See, for example, FIG. 2 illustrating an optical film 202 that covers less than the total surface of the solar panel 204. In such a case, it is anticipated that the resulting degradation in performance of the solar panel due to the optical film would only be a few percent power penalty. This approach would provide significantly enhanced commercial value to an electronic device, being especially valuable for consumer markets.

According to an embodiment of the present invention, as shown in FIG. 4, an exemplary wireless device 400 is illustrated. The wireless device 400, in this example, can operate in a wireless network using a standard communication protocol such as Code Division Multiple Access (CDMA), Time Division Multiple Access (TDMA), Global System for Mobile Communications (GSM), General Packet Radio Service (GPRS), Frequency Division Multiple Access (FDMA), or the like. Additionally, the wireless device 400 can communicate using text messaging standards, for example, Short Message Service (SMS), Enhanced Messaging Service (EMS), Multimedia Messaging Service (MMS), or the like. The wireless device 400, in this example, comprises a two-way radio capable of receiving and transmitting radio frequency signals over a communication channel under a communications protocol such as CDMA, FDMA, TDMA, GPRS, GSM or the like.

The wireless device 400 operates under the control of a device controller/processor 408, that switches the wireless device 400 between receive and transmit modes. In receive mode, the device controller 408 electrically couples an antenna 414 to a receiver in an RF Interface 412. The receiver decodes the received signals and provides those decoded signals to the device controller 408. In transmit mode, the device controller 408 electrically couples the antenna 414 to a transmitter in the RF Interface 412. The device controller 408 operates the transmitter and receiver in the RF Interface 412 according to instructions stored in the memory 410. Additionally, the memory 410 stores data from a received message for playback of the message to a user of the wireless device 400.

The wireless device 400 further includes an audio input/output interface 420 that receives decoded audio output signals, such as from the receiver in the RF Interface 412. The audio input/output interface 420 sends the received decoded audio signals to an audio output conditioning circuits that perform various conditioning functions such as to reduce noise or amplify the signal. A speaker (not shown) receives the conditioned audio signals and allows audio output for listening by a user. The wireless device 400 further includes additional user output interfaces, for example, a head phone jack (not shown) or a hands-free speaker (not shown) or an audible indicator (not shown).

The wireless device 400 also includes a microphone (not shown) for allowing a user to input audio signals into the wireless device 400. Sound waves are received by the microphone and are converted into an electrical audio signal. Audio input conditioning circuits receive the audio signal and perform various conditioning functions on the audio signal, for example, noise reduction. An audio input controller in the audio 10 interface 420 receives the conditioned audio signal and sends the signal to the device controller 408. The device controller 408 then can route the audio signals to a destination such as to the transmitter in the RF Interface 412 such as for transmitting into a wireless network, or such as to store in memory 410 the audio signals.

The wireless device 400 also comprises a user input interface 416 that includes a keyboard (not shown), and other user input devices such as buttons and switches, for allowing a user to enter user input information into the wireless device 400. The wireless device 400 further comprises a camera (not shown) for allowing a user to capture still images or video images into memory 410. Furthermore, the wireless device includes additional user input interfaces, for example, touch screen technology (not shown), a joystick (not shown), or a scroll wheel (not shown).

A user output interface includes a display (not shown) for displaying information to a user. A visual indicator (not shown) such as LED, lamp, or other visual indication on the display (not shown) is also included in the user output interface.

The electronic device 400 also includes a power source 406, such as a rechargeable battery. Power conditioning circuits 404 interface and condition power signals received from one or more solar panels, in this example arranged as a solar panel array 402. The conditioned power signals are coupled by the power conditioning circuits 404 to the power source 406. The one or more solar panels 402 collectively can provide significant power for recharging the battery to enhance the overall battery life of the power source 406.

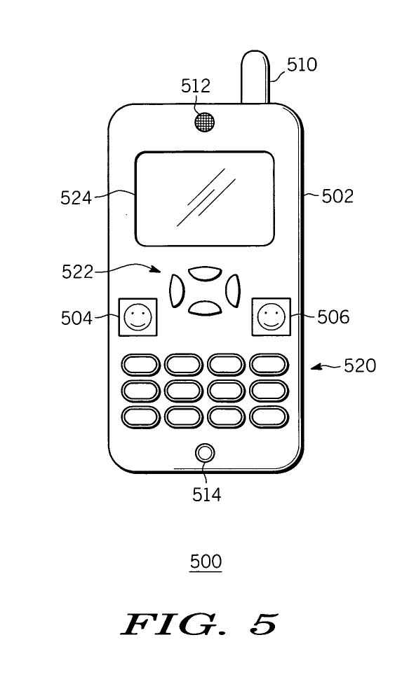

As illustrated in FIG. 5, an exemplary wireless device 500 includes a housing 502 that contains electronic circuits and components of the device 500. The housing 502 supports two exemplary solar panel arrangements 504, 506. Each of these two solar panel arrangements 504, 506, includes wavelength selectively reflective optical film disposed in front of a solar panel. As can be seen in FIG. 5, there is significant exposed surface area on the housing 502 of the device 500 that can be utilized for capturing solar energy by solar panel array. Any surface area that is typically exposed to external light may be available for use in enhancing power capture for the electronic device 500.

As has been discussed above with reference to FIG. 4, there are various user interfaces in a device 500 that consume external surface areas of the housing 502. For example, as shown in FIG. 5, there is an antenna 510, an earpiece (speaker) 512, a mouthpiece (microphone) 514, a keypad 520, buttons 522, and a display 524. There are other interfaces that may also use up external surface areas of the housing 502, such as a computer connection interface, an external charging and power adaptor interface, and the like, as should be obvious to those of ordinary skill in the art in view of the present discussion. Solar panel technology utilizing an embodiment of the present invention can be exposed over and/or in close proximity to any of these interfaces, as well as over the large exposed surface areas of the device 500.

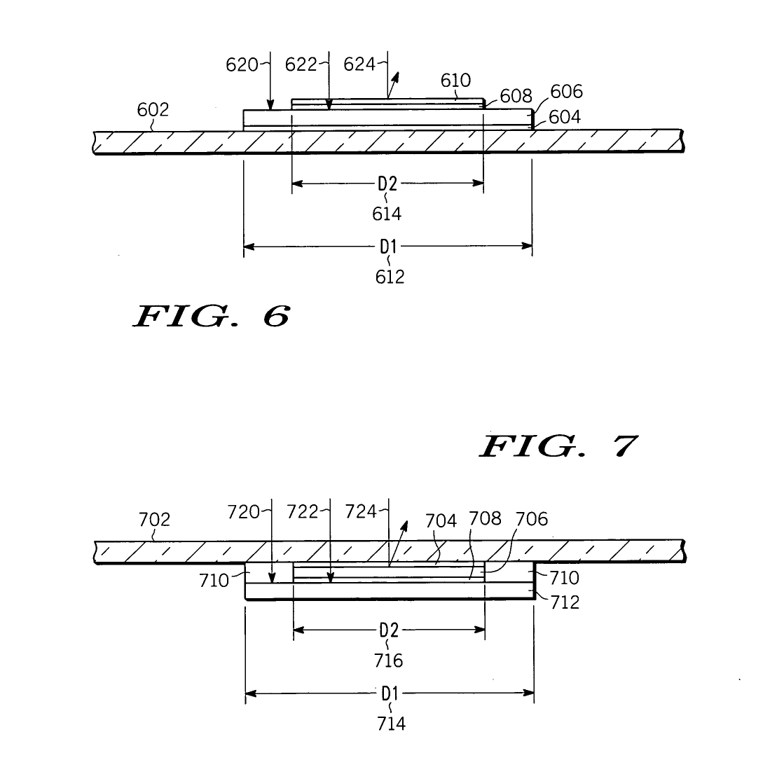

As illustrated in FIG. 6, a housing 602 of an electronic device can include a solar panel 606 attached by adhesive 604 to an outer surface area of the housing 602. The solar panel 606 is shown having a length 612 indicated by the symbol D1. A wavelength selectively reflective optical film 610 is attached by optically clear adhesive 608 to an outer surface area of the solar panel 606. The film 610 has a length 614 indicated by the symbol D2. As shown in FIG. 6, D2 is less than D1. That is, the film 606 only covers a portion of the surface area of the solar panel 606. Irradiation 620 can therefore directly reach the solar panel 606. Also, irradiation 622, 624, may travel to the outer surface of the film 610 such that most of this irradiation 622 reaches the solar panel 606 and a small portion of the irradiation 624 is reflected as visible light for viewing by a user of the electronic device. Note that the film 610 could be sized by design to cover any portion of the solar panel 606 including 100% coverage of the panel 606. Additionally, the film 610 provides additional protection to the outer surface of the solar panel 606. The film for example helps protect against damage to the outer surface of the panel 606.

FIG. 7 shows an alternative exemplary arrangement where the housing 702 of an electronic device can include a solar panel 712 and a wavelength selectively reflective optical film 706 that are attached by optically clear adhesive 704, 710, to an inner surface area of the housing 702. The housing 702, at least in the general area covering the solar panel 712, is made of substantially optically transparent (or at least optically non-blocking) material that allows solar irradiation to substantially transmit through the housing 702 to the solar panel 712. The solar panel 712 is attached by optically clear adhesive 708 to the back surface of the wavelength selectively reflective optical film 706. The solar panel 606 is shown having a length 714 indicated by the symbol D1. The film 706 has a length 716 indicated by the symbol D2. As shown in FIG. 7, D2 is less than D1. That is, the film 706 only covers a portion of the surface area of the solar panel 712. Of course, the film 706 could be sized by design to cover any portion of the solar panel 712 including 100% coverage of the panel 712. A significant benefit of locating the solar panel inside the housing is the enhanced protection provided to the solar panel. The external surface of the housing can be left smooth, and/or textured as necessary in places, to provide customized form and function for particular requirements of an application, while utilizing maximum surface area of the housing for the solar energy capture function in accordance with the present invention.

While the examples shown in FIGS. 6 and 7, and discussed above, show the film attached to the solar panel by the optically transparent adhesive, it should be obvious to those of ordinary skill in the art in view of the present discussion that the optical film only need be disposed in front of the solar panel. For example, the film could be attached to an outer surface of the housing while the solar panel could be attached to an inner surface of the housing. As a second alternative example, the solar panel could be disposed on an inner structure inside the device housing, such as on a printed circuit board, and the wavelength selectively reflective optical film could be disposed generally in front of the solar panel, such as by being attached to a front surface of the panel, or alternatively attached to an outer or an inner surface of the housing. As a third example, the wavelength selectively reflective optical film could be incorporated into the housing material such that the solar panel could be disposed inside, and/or on an inner surface, of the housing and the wavelength selectively reflective optical film could be integrated inside and/or be a part of the housing material. Other alternative arrangements of the housing, film, and solar panel, should become obvious to those of ordinary skill in the art in view of the present discussion.

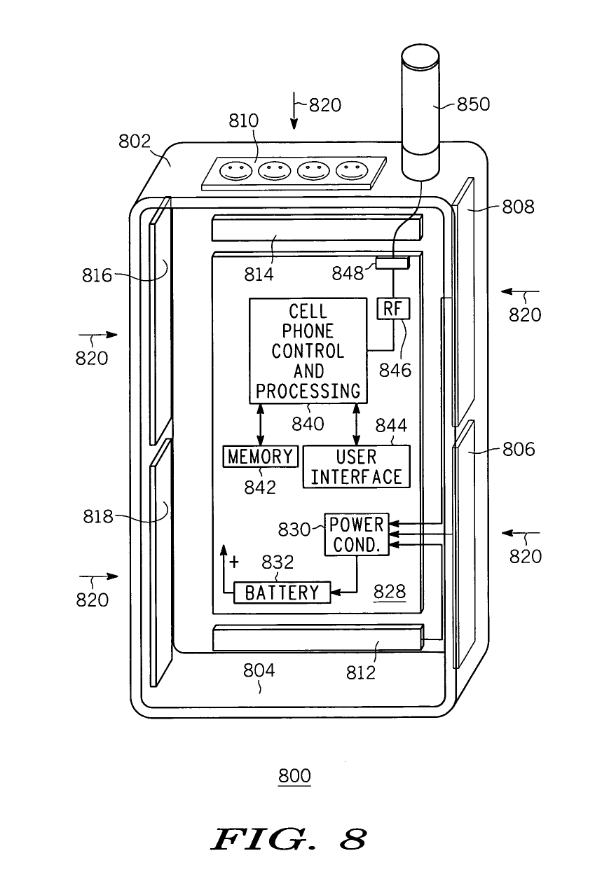

FIG. 8 illustrates an exemplary wireless device 800 with a housing 802 supporting an array of solar panels disposed on various surfaces of the housing 802. The front face of the device 800 is removed for clarity in the present discussion. The solar panels in this example are shown attached to an inner surface 804 of the housing 802. The housing material is selected by design to be substantially transparent to solar irradiance 820 for compatibility with the response of the solar panels 806, 808, 810, 812, 814, 816, 818. The solar panels 806, 808, 810, 812, 814, 816, 818, are individually covered by wavelength selectively reflective optical film that can be visually attractive, and/or convey advertising messages, to a user of the device 800. As can be seen, the various solar panels 806, 808, 810, 812, 814, 816, 818, are disposed on the inner surface 804 of the various walls of the housing 802 of the device 800. Also, mounted inside the housing is a printed circuit board (a circuit supporting substrate) 828 that supports circuits and a battery 832 for the wireless device 800. The board 828 supports the battery 832 and the power conditioning circuits 830 that couple collected power from the array of solar panels 806, 808, 810, 812, 814, 816, 818, to the operating circuits of the electronic device 800. As has been discussed above, the wireless device includes, for example, a controller/processor 840, a memory 842, and user input and output interface circuits 844. The board 828 also includes an RF interface 846 that via a connector 848 couples through a coaxial cable with the antenna 850. By utilizing a large array of solar panels 806, 808, 810, 812, 814, 816, 818, the wireless device 800 can collect significant solar power for recharging the battery as necessary. This will significantly extend the battery life of the battery thereby enhancing the commercial viability of an electronic device such as the wireless device 800 shown in FIG. 8.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A solar panel mounting arrangement comprising:
a solar panel; and
a wavelength selectively reflective optical film being disposed in front of the solar panel for the optical film to substantially reflect a pre-selected band of solar irradiation frequencies in the visible light range on a front surface of the optical film while allowing solar irradiation frequencies outside of the pre-selected band to substantially pass through the optical film and irradiate the solar panel.

2. The solar panel mounting arrangement of claim 1, wherein the optical film is attached to a front surface of the solar panel by an optically clear adhesive thereby allowing solar irradiation frequencies outside of the pre-selected band to substantially pass through the optical film and the adhesive and to irradiate the solar panel.

3. The solar panel mounting arrangement of claim 1, further comprising a housing for an electronic device, the housing having an inner surface and an outer surface and at least a portion of the housing being substantially optically transparent to solar irradiation, and wherein the optical film is attached to one of the outer surface and the inner surface of the housing about the at least a portion of the housing being substantially optically transparent to solar irradiation thereby allowing solar irradiation frequencies outside of the selected band to substantially pass through the optical film and the at least a portion of the housing being substantially optically transparent to solar irradiation, and to irradiate the solar panel.

4. The solar panel mounting arrangement of claim 3, wherein the optical film is attached by an optically clear adhesive to the one of the outer surface and the inner surface of the housing about the at least a portion of the housing being substantially optically transparent to solar irradiation thereby allowing solar irradiation frequencies outside of the pre-selected band to substantially pass through the optical film, the adhesive, and the at least a portion of the housing being substantially optically transparent to solar irradiation, and to irradiate the solar panel.

5. The solar panel mounting arrangement of claim 1, wherein the optical film comprises at least one of an iconic pattern, a company logo, and a photo.

6. The solar panel mounting arrangement of claim 1, wherein the optical film covers less than the entire front surface of the solar panel from the solar irradiation.

7. The solar panel mounting arrangement of claim 1, wherein the optical film comprises holographic film.

8. The solar panel mounting arrangement of claim 1, wherein the optical film comprises a multi-layer film.

9. An electronic device comprising:
a power source;
electronic circuits, electrically coupled with the power source;
a solar panel, electrically coupled with the power source; and
a wavelength selectively reflective optical film being disposed in front of the solar panel for the optical film to substantially reflect a pre-selected band of solar irradiation frequencies in the visible light range on a front surface of the optical film while allowing solar irradiation frequencies outside of the pre-selected band to substantially pass through the optical film and irradiate the solar panel.

10. The electronic device of claim 9, further comprising:
a housing for containing the electronic circuits, and wherein the solar panel being mechanically coupled with the housing and located to allow solar irradiation outside of the housing to substantially irradiate the solar panel.

11. The electronic device of claim 10, wherein the solar panel being mounted inside the housing, at least a portion of the housing being substantially optically transparent to solar irradiation thereby allowing solar irradiation frequencies outside of the pre-selected band to substantially pass through the optical film and the at least a portion of the housing being substantially optically transparent to solar irradiation, and to irradiate the solar panel.

12. The electronic device of claim 9, wherein the optical film is attached by an optically clear adhesive to a surface of the housing about at least a portion of the housing being substantially optically transparent to solar irradiation thereby allowing solar irradiation frequencies outside of the pre-selected band to substantially pass through the optical film, the adhesive, and the at least a portion of the housing being substantially optically transparent to solar irradiation, and to irradiate the solar panel.

13. The electronic device of claim 9, wherein the optical film comprises at least one of an iconic pattern, a company logo, and a photo.

14. The electronic device of claim 9, wherein the optical film covers less than the entire front surface of the solar panel from the solar irradiation.

15. The electronic device of claim 9, wherein the optical film comprises holographic film.

16. The electronic device of claim 9, wherein the optical film comprises a multi-layer film.

17. A wireless device comprising:
a power source;
electronic circuits, electrically coupled with the power source, the electronic circuits including a receiver for receiving wirelessly transmitted signals;
at least one solar panel, electrically coupled with the power source; and
at least one wavelength selectively reflective optical film being disposed in front of the at least one solar panel for the at least one optical film to substantially reflect a pre-selected band of solar irradiation frequencies in the visible light range on a front surface of the at least one optical film while allowing solar irradiation frequencies outside of the pre-selected band to substantially pass through the at least one optical film and irradiate the at least one solar panel.

18. The wireless device of claim 17, further comprising a housing, and wherein the at least one solar panel is a plurality of solar panels and wherein the at least one wavelength selectively reflective optical film is a plurality of wavelength selectively reflective optical films, the plurality of solar panels being electrically coupled with the power source and further being disposed on various surfaces of the housing to enhance collection of power from solar irradiance on the various surfaces.

19. The wireless device of claim 17, wherein the at least one optical film comprises holographic film, and wherein the at least one optical film further comprises at least one of an iconic pattern, a company logo, and a photo, visible from a front surface of the at least one optical film.

20. The wireless device of claim 15, wherein the at least one optical film comprises a multi-layer film.
